(19) United States
(12) Patent Application Publication
(10) Pub. No.: US 2007/0184187 A1
(43) Pub. Date: Aug. 9, 2007

(54) Process for the preparation of a composite material

(75) Inventor: Shahab M. Jahromi, Maastricht (NL)

Correspondence Address: NIXON & VANDERHYE, PC, 901 NORTH GLEBE ROAD, 11TH FLOOR, ARLINGTON, VA, 22203, US

(73) Assignee: DSM IP ASSETS B.V., TE HEERLEN (NL)

(21) Appl. No.: 10/556,081

(22) PCT Filed: May 10, 2004
(86) PCT No.: PCT/NL04/00312

§ 371 Date: Mar. 22, 2007

(30) Foreign Application Priority Data
May 15, 2003 (NL) 03/000361

(51) Int. Cl. C23C 16/00

(52) U.S. Cl. 427/248.1

(57) ABSTRACT

The invention relates to a process for the preparation of a composite material comprising a substrate, a first layer and a second layer, comprising a first vapor-depositing step, wherein a first compound is vapor-deposited on the substrate, whereby the first layer is formed, and a second vapor-depositing step, wherein a second compound comprising a triazine compound is vapor-deposited on the first layer, whereby the second layer is formed, whereby the first and second vapor-depositing steps are carried out in such a way that the first layer comprises between 0 wt. % and 10 wt. % of a triazine compound.

The invention relates to a process for the preparation of a composite material. The invention further relates to an apparatus for carrying out said process.

A process for the preparation of a composite material is known from WO 99/66097. In the process of WO 99/66097, a layer is vapour-deposited on a substrate; the vapour-deposited compound comprises a triazine compound.

It is the objective of the present invention to provide an improved process by which a composite material can be prepared having additional properties, improved properties such as barrier properties, or a combination thereof.

The said objective is achieved by a process for the preparation of a composite material comprising a substrate, a first layer and a second layer, comprising
a first vapour-depositing step, wherein a first compound is vapour-deposited on the substrate, whereby the first layer is formed, and
a second vapour-depositing step, wherein a second compound comprising a triazine compound is vapour-deposited on the first layer, whereby the second layer is formed,
   whereby the first and second vapour-depositing steps are carried out in such a way that the first layer comprises between 0 wt. % and 10 wt. % of a triazine compound.

An advantage of the process according to the invention is that, while the first vapour-depositing step allows the incorporation of any feasible desired property onto the substrate, the second vapour-depositing step—and the carrying out thereof such that the triazine compound is present in the first layer in between 0 wt. % and 10 wt. %—confers barrier properties on the substrate without deteriorating the functionality of the first layer.

In the process according to the invention, a composite material comprising a substrate, a first layer and a second layer is prepared. The substrate is the material that serves as carrier of the layers; it is the object on which the layers are to be deposited. The substrate may consist essentially of a homogeneous material, or it may itself be non-homogeneous or a composite material. The substrate may comprise various layers. The substrate may be essentially flat, or it may have a complex three-dimensional shape. Examples of suitable substrates are flexible packagings such as films, tools, rigid packagings such as bottles or pre-shaped packaging boxes.

Preferably, the substrate comprises a polymeric material, paper, cardboard, metal, or ceramic. If the substrate itself does not adhere sufficiently to the compound comprised in the first layer, it may be necessary to execute a pre-treatment of the substrate prior to the vapour-depositing steps. Examples of such pre-treatments are corona- and plasma treatments.

The process according to the invention comprises a first vapour-depositing step. This step may be carried out by methods known in the art. Preferably, the first vapour-depositing step is carried out under reduced pressure, i.e. a pressure below atmospheric pressure. More preferably, the first vapour-depositing step is carried out at a pressure below 1000 Pa or below 1 Pa, or even below 0.5 Pa, most preferably between 0.001 Pa and 0.01 Pa.

During the first vapour-depositing step, temperature gradients are present: the first compound must be heated to such a temperature that it vaporises, whereas the substrate must have a temperature sufficiently low so that the vapour deposits on it upon contact. All these circumstances are well known to those skilled in the art.

In the first vapour-depositing step, the first compound is vaporised; the vapour is subsequently brought into contact with the substrate upon which it then deposits. The wording compound means, here and hereafter, either a pure substance or a mixture of two or more substances. The first compound may be any compound suitable for the intended purpose it serves; these compounds and their intended purposes are as such known in the art. Examples of preferred substances suitable as the first compound are: a metal such as aluminium; a metal oxide such as aluminium oxide (AlOₓ), whereby it is possible that the metal oxide is formed via oxidation of the metal after depositing; other oxides such as silicon oxide (SiOₓ). Organic compounds may also serve as the first compound; in a preferred embodiment, the first compound does not comprise a triazine compound.

Upon being deposited, the first compound forms the first layer. The thickness of the first layer depends on its intended purpose, and can thus vary within wide limits. Preferably, the thickness of the first layer is less than 100 μm, more preferably less than 10 μm, and even more preferably less than 1 μm; the minimum thickness is preferably at least 2 nm, more preferably at least 10 nm. If the first compound does not show sufficient adhesion to the substrate, it may be necessary to execute a pre-treatment of the substrate prior to the vapour-depositing steps. Examples of such pre-treatments are corona- and plasma treatments.

Subsequent to the first vapour-depositing step, the process according to the invention comprises a second vapour-depositing step. This second vapour-depositing step is executed according to the same principles as the first vapour-depositing step. Thus, the second compound is vaporised; the vapour is then transported and deposits on the first layer, thus forming the second layer. The first and second vapour-depositing steps may be executed as one continuous process, or they may be executed as two separate continuous or batch processes.

The second compound comprises a triazine compound, preferably a 1,3,5-triazine since many 1,3,5-triazines show in their application according to the invention a number of beneficial properties such as gas barrier properties, non-toxicity, scratch resistance, and the possibility to form transparent layers at certain thicknesses. Examples of triazines that can be utilised in the second compound in the process according to the invention are melamine, melem, melam, ammeline, ammelide, cyanuric acid, 2-ureidomelamine, melamine salts such as melamine cyanurate, melamine functionalised with polymerisable groups such as acrylates, epoxies, vinyl ethers. The second compound may comprise a mixture of triazine compounds and may also comprise additional compounds such as compounds intended for subsequent chemical reactions such as functionalising, resin-forming, polymerising, or cross-linking.

When vapour-deposited, the triazine compound usually has not chemically reacted; it is then in non-resinous, crystalline form, usually not in the form of one single-crystal but in the form of grains which are separated by boundaries. Such grains are, for crystallisable compounds in general, commonly known to persons skilled in the art. It has been found, surprisingly, that the barrier properties of the composite material according to the invention as conferred by the second compound depend on, amongst others, the size of the deposited grains, in particular on the size of the triazine-containing grains. Grain size is defined herein as the largest dimension, parallel to the surface of the substrate (i.e. as seen from top), within a single grain. The size of the triazine-containing grains in the second layer may be as important as, or may even be more important than the thickness of the second layer in determining important characteristics such as barrier properties. Without committing to any specific theoretical explanation, it is thought that optimal barrier properties are achieved by, contrary to what the skilled person might expect, focusing on the amount and size of the boundaries between the grains rather than focusing on the thickness of the deposited layer. It is thought that boundaries between grains are relative weak spots in conferring barrier properties to the composite material; thus, if the average grain size becomes too small, there are so many boundaries that barrier properties are negatively influenced. On the other hand, if the average grain size becomes too big, it is thought that the boundary areas themselves become bigger disproportionately, so that, again, barrier properties suffer. The average grain size is preferably at least 10 nm, more preferably at lease 50 nm, even more preferably at least 100 nm and most preferably at least 200 nm. The average grain size is preferably at most 2000 nm, more preferably at most 1000 nm, even more preferable at most 600 nm and most preferably at most 400 nm. Average grain size is meant herein as being the numbered average. In a preferred embodiment, the second compound essentially consists of the triazine compound so that the triazine crystal structures are not significantly interrupted.

The average size of a vapour-deposited grains depends a.o. on the number of nucleation points on the surface on which the grains grow: the higher the number of nucleation points, the smaller the average grain size will be. The average size of the deposited grains can thus be varied by adjusting those process conditions during the second vapour-depositing step that influence the number of nucleation points from which grains grow. It has been found according to the invention that the number of nucleation points increases with increasing temperature difference between the deposition temperature, i.e. the temperature to which the triazine-containing second compound is heated, and the first layer. Also, it was found that the number of nucleation points decreases if the pressure is increased at which the second vapour-depositing step is done. Furthermore, it should be noted that the nature of the first layer also has an influence on the number of nucleation points that are being formed. The person skilled in the art can thus, using the teachings regarding the parameters of temperature difference and pressure as given, determine via experimentation what the optimal process conditions for the second vapour-depositing step are in order to achieve an average grain size within the range as given above.

Although the second layer comprising the triazine compound in non-resinous crystalline form demonstrates the desired properties such as gas barrier properties, it may be advantageous to execute a subsequent step in which the triazine compound is physically or chemically altered. Examples of such subsequent steps are a crosslinking step, and a plasma-, corona-, UV- or electron beam treatment. In a crosslinking step, the triazine compound reacts with itself or with another compound; said other compound may be co-vapour-deposited into the second layer or may be brought into contact with the second layer after it has formed. An example of such an other compound is gaseous formaldehyde. The execution of said subsequent steps may be desirable in order to enhance certain specific properties such as scratch resistance or resistance to humidity.

As is the case with the first layer, the thickness of the second layer may vary within wide limits, depending on its intended purpose. Preferably, the thickness of the second layer is less than 100 μm, more preferably less than 10 μm or even less than 1 μm; the minimum thickness is preferably at least 2 nm, more preferably at least 10 nm.

During execution of the first and the second-vapour-depositing step, it is important to ensure that the triazine compound does not form a large portion of the first layer, although the presence of a small amount of a triazine compound in the first layer may, depending on the nature of the first compound and the desired characteristics of the composite material, provide a beneficial effect. The presence of a high amount of the triazine compound in the first layer can for example occur if the first and second vapour-depositing steps are executed immediately after each other, so that the vapour of the first compound and the vapour of the second compound mix with each other. Another example of the possibility that the triazine compound becomes a large portion of the first layer is when the first layer is not yet solidified when vapour-depositing of the second layer is done. The first layer should not comprise more than 10 wt. % of a triazine compound; preferably, the first layer comprises less than 5 wt. %, more preferably less than 3 wt. % or even less than 1 wt. % of a triazine compound. In a preferred embodiment, the first layer is essentially free of any triazine compounds. The technical measures needed in order to ensure that the first layer does not comprise more than 10 wt. % of the triazine comprised in the second compound will depend on the concrete fashion in which the first and second vapour-depositing steps are executed. Examples of such measures are: the presence of a physical barrier such as a screen between the vapour of the first compound and the vapour of the second compound; the provision of sufficient distance between the two sources of the vapors, whereby a distance of 50 cm, 100 cm, 500 cm or preferably 1000 cm or even 3000 cm can be observed; the execution of the first and second vapour-depositing steps in separate chambers, whereby in the case of continuous production only openings large enough to let the substrate or the substrate with layer or layers through. In the latter case it may be preferred that the two chambers are place inside a larger chamber, so that the conditions, in particular relating to pressure, of the whole system can be controlled.

The pressures in the first and the second vapour-depositing steps can be virtually equal. In an embodiment of the process according to the invention, however, the pressure in the second vapour-depositing step is at least 0.0005 Pa lower or higher than the pressure in the first vapour-depositing step. This is advantageous, since the optimal pressure for carrying out a vapour-depositing step can vary per compound so that in this embodiment each vapour-depositing step can be executed at the pressure, optimal for the specific compound. Another advantage is that the differentiation of pressures allows for taking characteristics of previous or subsequent operations into account. An example of such an operation is the winding of a film in case the substrate is a continuous film; it is known that the ease of carrying out such a winding step is pressure-dependent. Furthermore, if at least one vapour-depositing step is carried out under reduced pressure, it is not necessary that both vapour-depositing steps are carried out at the lowest pressure, i.e. the deepest vacuum, so that the stringent technical measures needed for achieving the deepest vacuum are only necessary for one vapour-depositing step. Preferably, the second vapour-depositing step is at least 0.005 or 0.01 Pa higher or lower than the first vapour-depositing step, more preferably at least 0.1 Pa, or even at least 1 Pa. It is generally advisable that the difference in pressure between the first and second vapour-depositing steps is not bigger than 100000 Pa, preferably 10000 Pa, more preferably 1000 Pa. In an alternative embodiment of choosing the pressure conditions in the first and the second vapour-depositing steps, the difference in pressure between the two steps is at least a factor 5, preferably a factor 10, more preferably a factor 25.

In an embodiment of the invention, the first compound is chosen such that the first layer provides a gas—or fluid barrier. Metals and/or oxides of metals such as aluminium or its oxide are examples of suitable substances providing such barrier action. In this fashion, the combined barrier actions of the first and second layer will provide an enhanced security of barrier properties of the composite material, especially in case of scratches or other damages occurring so that the second layer also acts as protective layer.

In a preferred embodiment of the process according to the invention, the said process is carried out at a pressure below 1000 Pa; preferably, the pressure is 10 Pa or lower, more preferably 1×10⁻¹ Pa or lower, more preferably 4×10⁻³ Pa or lower, even more preferably 5×10⁻⁴ Pa or lower, most preferably 1×10⁻⁴ Pa or lower or even 5×10⁻⁵ Pa or lower. Preferably, the second vapour-depositing step is carried out immediately after or shortly after the first vapour-depositing step, i.e. within 5 minutes or less, or 1 minute or less, or 45 seconds or less, or even 30 seconds or less, in particular 20 or 10 seconds or less, most particularly 5 seconds or less or even 2 seconds or less. One method of ensuring that the two vapour-depositing steps are executed within a short period of time is by means of a continuous or semi-continuous process, whereby the two steps are carried out in one vacuum chamber or in two adjacent vacuum chambers, and whereby the substrate is transported by known means such as conveyor belts or a system or rolls in case the substrate is a film. The substrate is brought into contact with a first cooling surface during the first vapour-depositing step, said first cooling surface having a temperature T₁. If the substrate is in the form of a film, the first cooling surface will usually be in the form of a temperature-controlled roll, also referred to as a coating drum. Typically, the temperature is controlled by bringing a part of the substrate which will not be vapour-deposited in contact with a cooling or heating surface, such as a temperature-controlled roll—or coating drum—in case the substrate is a film. A film means within the context of the present invention an essentially flat substrate having a thickness of at most 2000 μm, preferably at most 1000 μm, in particular at most 800 μm and most preferably at most 500 μm. In practice, film thicknesses in the region of 10 μm to 50 μm are also quite common.

During the first vapour-depositing step, the temperature of the substrate will change under the influence of the first cooling surface. The temperature of the substrate will also be influenced by the temperature of the first compound as it deposits on the substrate. Depending on the nature of the first compound, this influence can be significant. For example, metals like aluminium are typically vaporized at temperatures well above 1000° C. As a result of the contact with the first cooling surface and as a result of the thermal energy as present in the first compound, the substrate with the first layer will have—after completion of the first vapour-depositing step—a resulting average temperature. Subsequently, the substrate with the first layer enters the second vapour-depositing step. The average temperature of the substrate with the first layer at that moment is herein defined as temperature T_{S1}. The substrate with the first layer is brought into contact with a second cooling surface during the second vapour-depositing step, said second cooling surface having a temperature T₂. In this embodiment according to the invention, T₂ should be chosen such that the difference between T_{S1} and T₂ is less than 50° C. It was found, surprisingly, that the adhesion between the second layer and the first layer increases when there is a decreasing difference between T_{S1}, and T₂ during the second vapour-depositing step. It is thus an advantage of this embodiment according to the invention that a composite material is obtained having improved properties, in particular regarding the adhesion between the first and the second layer. Preferably, T₂ is chosen such that the difference between T_{S1} and T₂ is less than 30° C. or 20° C., in particular less than 10° C. or even 5° C.

From the above, it will be evident to the skilled person that the level of T₁ as set will have an influence on T_{S1}; especially so in view of the preferred short time between execution of the first and second vapour-depositing steps, and in view of the reduced pressure under which the vapour-depositing steps are carried out, which sharply reduces heat exchange between the substrate with the first layer and its surrounding atmosphere. Consequently, the level of T₁ as set will thus also have an influence on the resulting level at which T₂ must be set: a reduction of T₁, will, all other circumstances being the same, lead to a stronger cooling of the substrate during the first vapour-depositing step, so that T_{S1} will also be lower thereby setting an operating window for T₂ at lower temperature levels. Preferably, T₁is chosen such that T₂ can lie between−20° C. and +75° C., more preferably between−10° C. and +60° C. , in particular between 0° C. and +50° C. This has the advantage that substrates can be treated in the process according to the invention that are not capable of withstanding very high or very low temperatures, such as for example substrates comprising polymeric films.

As is known to the skilled person, it is possible to influence the effect of a certain fixed T₁ on the resulting substrate temperature, for example by increasing or decreasing the cooling surface with which the substrate is contacted, and/or the time during which the substrate is contacted with the cooling surface. Preferably, these and other relevant parameters as known to the skilled person are chosen such that T₁can lie between −30° C. and +30° C., in particular between −15° C. and +20° C., while ensuring that T₂ can lie between −20° C. and +75° C., more preferably between −10° C. and +60° C., in particular between 0° C. and +50° C. This has the advantage that the temperature-controlling measures that are needed in order to set the temperature of the first cooling surface are within commonly used parameters.

Preferably, the first compound comprises or even consists essentially of aluminium, aluminium oxide, or silicon oxide; preferably, the second compound comprises or even consists essentially of melamine.

In an alternative embodiment of the process according to the invention, the substrate with the first layer, having an average temperature T_{S1}, is brought into contact during the second vapour-depositing step with a second cooling surface having an adjustable temperature T₂, whereby the process is operated in such a way that the difference between T_{S1} and T₂ is maintained at less than 30° C. Preferably, the said difference between T_{S1} and T₂ is maintained at less than 10° C., in particular at less than 5° C. As in the previous embodiment, a decreasing difference between T_{S1} and T₂ has the advantage that the adhesion between the first layer and the second layer is increased. Compared to the previous embodiment, this embodiment has the advantage that it becomes possible to operate the first vapour-depositing step more independently from the first vapour-depositing step. Thus, it can for example be possible to adjust the temperature of the substrate with the first layer as it enters the second vapour-depositing step. Preferably, T_{S1} is adjusted so that T₂ can lie between −20° C. and +75° C., more preferably between −10° C. and +60° C., in particular between 0° C. and +50° C.

Immediately after completion of the second vapour-depositing step, the now prepared composite material has an average temperature T_{c}. Depending on the specific circumstances, T_{c} may lie above room temperature. If this is so, it is preferred to execute, immediately subsequent to the second vapour-depositing step, a cooling step in which the T_{c} is reduced to ambient temperature. This cooling step can be executed by techniques known per se, such as the exposure to ambient air or exposure to temperature-controlled air. In this embodiment, the cooling rate at which T_{c} is reduced should be no more than, 10° C. per hour. This has the advantage that any thermal stresses present in the composite material can relax without significantly deteriorating the structure of the composite material itself, through crack formation or the such. This is particularly relevant in case the first compound comprises a non-organic compound such as a metal. Preferably, the cooling rate is 8° C. or 5° C. or less per hour; more preferable the cooling rate is 3° C. or less per hour.

In another embodiment of the process according to the invention, the substrate and the first layer are subjected to a mechanical loading step prior to or during the second vapour-depositing step. A mechanical loading step is understood herein to be a step wherein the substrate is physically deformed as a result of external stress being applied to the substrate, whereby the deformation is preferably not permanent as far as the substrate is concerned. Examples of mechanical loading steps are stretching, bending, curving, and twisting. If the substrate is a film, an example of a mechanical loading step is the guiding of the film over a roll. Preferably, the substrate is deformed by at least 0.3%, more preferably by at least 0.5% or 1%, most preferably by at least 3%. In order to avoid structural damage to the composite material, the substrate is preferably deformed by not more than 100%, more preferably by not more than 50%, most preferably by not more than 25%. During the mechanical loading step, the substrate and the first layer are subjected to mechanical stresses—as they will be in practice as well. As a result of said stresses, small defects in the first layer may arise. These defects will be covered with the second compound, since the mechanical loading step is done prior to or during the second vapour-depositing step. In this fashion, the composite material according to the invention is pre-treated for practice, ensuring that certain properties sought in both the first and the second compound, such as for example gas barrier properties, and properties sought specifically in the second compound will be better preserved in case the composite material is in its application subjected to stresses.

A further embodiment of the process for the preparation of a composite material according to the invention comprises the step of applying a third or even a still further layer on top of the second layer. The presence of a third or further layer(s) may be desirable if additional or different properties are required of the composite material, such as for example properties relating to decorative use or protection, electrical conductivity, and/or chemical nature such as polarity. An example of third and further layers applied on top of the second layer is: a print layer as third layer, an adhesive layer as fourth layer and a sealant layer as fifth layer. The third and further layer(s) may be applied by any suitable means, such as for example vapour-depositing, coating, and laminating.

An apparatus in which the process according to the invention is executed should meet certain requirements, so that it is ensured that no more than 10% of the triazine compound is present in the first layer. The invention therefore also relates to such an apparatus; the apparatus comprises means for evaporating the first compound and the second compound, and means for separating the first compound and the second compound during vapour-depositing. These means may take various forms, depending a.o. on the nature of the compounds. Examples of said means are: the presence of a space of at least 50, 100, or 1000 cm between the means for evaporating the first and second compounds; the provision of a barrier between the means for evaporating the first and second compounds; the provision of separate chambers for carrying out the first and second vapour-depositing step.

If a mechanical loading step is to be done on the substrate, the apparatus in which the process according to the invention is carried out should comprise means for applying said mechanical loading step. Examples of such means are, in case the substrate is essentially flat, a roll or a set of rolls.

The invention will be further elucidated by means of the following Examples and Comparative Experiments.

### EXAMPLE 1

As substrate, a film of oriented polypropylene (OPP) of 12 μm thickness was chosen. On the OPP film, aluminium as the first compound was vapour-deposited. The first and second vapour-depositing steps were executed as batch process steps. The second compound consisted of melamine (supplier: DSM). The deposition temperature of the melamine was 310° C. The pressure during the second vapour-depositing step was 10⁵ Pa; the substrate and first layer had a temperature of −20° C. The second layer had a thickness of 140 nm; the average grain size was 60 nm. The aluminium layer comprised 0% melamine. On the composite material prepared as described, the oxygen transmission rate (OTR) was measured, at 0% relative humidity (RH). OTR is customarily expressed in cubic centimeters per square meter per day (cc/m².day). The lower the OTR value, the better the barrier properties relating to oxygen. The OTR of the composite material according to the invention was determined to be 10 cc/m².day.

### COMPARATIVE EXPERIMENT 1

The OTR of an OPP film treated in the same conditions as Example 1 but with only the first layer of aluminium deposited on it, i.e. without execution of the second vapour-depositing step, was measured at 0% RH and determined to be 18 cc/m².day. The comparative experiment illustrates that even though vapour-deposited aluminium is known to confer excellent barrier properties on substrates such as an OPP film, the composite material according to the invention surprisingly enhances the barrier properties even further.

### COMPARATIVE EXPERIMENT 2

Melamine was vapour-deposited on an OPP film. The melamine vapour-depositing temperature was 310° C. The OTR of this composite material was measured at 0% RH and determined to be 80 cc/m².day. This value is already significantly better than the OTR of the OPP film as such, which is known to be about 1600 cc/m².day. The OTR is, however, significantly worse than that of the composite material according to the invention of Example 1.

### COMPARATIVE EXPERIMENT 3

The OTR of the composite material prepared in Comparative experiment 2 was measured at 50% RH and determined to be in excess of 200 cc/m².day. This result indicates that the barrier properties of a composite material whereby an OPP film is the substrate and whereby melamine is directly vapour-deposited on the substrate are negatively influenced by humidity.

### EXAMPLE 2

The OTR of the composite material as prepared in Example 1 was measured at 50% RH and determined to be 10.2 cc/m².day. This example shows that the barrier properties of a composite material according to the invention whereby aluminium is chosen as first compound and whereby melamine is chosen as second compound are not sensitive to significant variations in relative humidity.

1. Process for the preparation of a composite material comprising a substrate, a first layer and a second layer, comprising:
a first vapour-depositing step, wherein a first compound is vapour-deposited on the substrate, whereby the first layer is formed, and
a second vapour-depositing step, wherein a second compound comprising a triazine compound is vapour-deposited on the first layer, whereby the second layer is formed,
whereby the first and second Vapour-depositing steps are carried out in such a way that the first layer comprises between 0 wt % and 10 wt. % of a triazine compound.

2. Process according to claim 1, wherein the first compound comprises a metal.

3. Process according to claim 1, wherein the first compound comprises aluminium, aluminium oxide, or silicon oxide.

4. Process according to claim 1, wherein the triazine compound in the second layer is crystalline.

5. Process according to claim 1, wherein the first compound comprises aluminium and the second compound comprises melamine.

6. Process according to claim 1, wherein the said process is carried out at a pressure below 1000 Pa and wherein the substrate is:
brought into contact with a first cooling surface during the first vapour-depositing step, said first cooling surface having a temperature T₁, whereby the resulting average temperature of the substrate upon entry into the second vapour-depositing step is a temperature T_{S1};
brought into contact with a second cooling surface during the second vapour-depositing step, said second cooling surface having a temperature T₂,
whereby T₂ is chosen such that the difference between T_{S1} and T₂ is less than 30° C.

7. Process according to claim 6, wherein T₂ is chosen such that the difference between T_{S1} and T₂ is less than 10° C., in particular less than 5° C.

8. Process according to claim 6, wherein T₁ is chosen such that T₂ can lie between −10° C. and +60° C., in particular between 0C and +50° C.

9. Process according to claim 8, wherein T₁ lies between −30° C. and +30° C., in particular between −15° C. and +20° C.

10. Process according to claim 1, wherein the substrate with the first layer, having an average temperature T_{S1}, is brought into contact during the second vapour-depositing step with a second cooling surface having an adjustable temperature T₂, whereby the process is operated in such a way that the difference between T_{S1} and T₂ is maintained at less than 30° C.

11. Process according to claim 10, wherein the said difference between T_{S1} and T₂ is maintained at less than 10° C., in particular at less than 5° C.

12. Process according to claim 10, wherein T_{S1} is adjusted so that T₂ can lie between −10° C. and +60° C., in particular between 0° C. and +50° C.

13. Process according to claim 1, wherein, immediately subsequent to the second vapour-depositing step, the temperature of the composite material T_{c} is reduced to ambient temperature in a cooling step, whereby T_{c} is in the cooling step reduced by 10° C. per hour or less.

14. Process according to claim 13, wherein T_{c} is in the cooling step reduced by 5° C. per hour or less, in particular by 3° C. per hour or less.

15. Process according to claim 6, wherein the pressure in the second vapour-depositing step is at least 0.005 Pa lower or higher than the pressure in the first vapour-depositing step.

16. Process according to claim 1, wherein the substrate and the first layer are subjected to a mechanical loading step prior to or during the second vapour-depositing step.

17. Process according to claim 1, comprising the step of crosslinking the triazine compound.

18. Process according to claim 1, comprising the step of plasma-treating the substrate, the first layer or the second layer.

19. Process according to claim 1, comprising the step of applying a third layer on top of the second layer.

20. Composite material, obtainable by the process of claim 1.
